(19) United States
(12) Patent Application Publication
(10) Pub. No.: US 2019/0372519 A1
(43) Pub. Date: Dec. 5, 2019

(54) ENERGY STORAGE TYPE SOLAR DEVICE

(71) Applicant: BOLYMEDIA HOLDINGS CO., LTD., Santa Clara, CA (US)

(72) Inventor: Xiaoping HU, Shenzhen, Guangdong (CN)

(73) Assignee: BOLYMEDIA HOLDINGS CO., LTD., Santa Clara, CA (US)

(21) Appl. No.: 16/488,926

(22) PCT Filed: Feb. 27, 2017
(86) PCT No.: PCT/CN2017/074983

§ 371 Date: Aug. 26, 2019

(51) Int. Cl. H02S 40/38; H02S 40/42; H02S 40/22; H02S 40/44; H01L 35/30; H02S 99/00; H02J 7/35

(52) U.S. Cl. CPC H02S 40/38; H02S 40/42; H02S 40/22; H02J 7/35; H01L 35/30; H02S 99/00; H02S 40/44

(57) ABSTRACT

An energy storage type solar device comprises a light convergence device (110), a photoelectric conversion device (120), a rechargeable battery (130), a thermal energy storage device (140), and a heat dissipation-insulation control mechanism (150). A heat storage substance (141) of the thermal energy storage device (140) is in thermally conductive connection with the photoelectric conversion device (120) and the rechargeable battery (130). In the energy storage type solar device, the thermal energy storage device (140) is used to store thermal energy, and the heat dissipation-insulation control mechanism (150) is used to controllably at least partially allow or prevent heat exchange between the heat storage substance (141) and an external environment, such that the photoelectric conversion device (120) and the battery can be cooled down in a hot weather condition and thermal insulation of the battery can be performed in a cold weather condition.

### TECHNICAL FIELD

The present disclosure relates to clean energy technical field, specifically to an energy storage type solar device.

### BACKGROUND

With the increasing attention on environmental protection, solar systems have been more and more widely used. Since the provision of sunlight has obvious time characteristics, the storage of solar energy has become an urgent need.

The most common energy storage method currently used is using battery. However, almost all types of battery have significant temperature effects. Some batteries, such as lithium-ion batteries, may not even work properly after the temperature exceeds a certain range, and may also cause a safety hazard. Therefore, energy storage type solar devices that are suitable for various climatic conditions are worthy of study.

### SUMMARY

The present disclosure may provide an energy storage type solar device, which may include: a light convergence device used for converging incident sun lights; a photoelectric conversion device used for converting received light energy into electrical energy, where a light receiving surface of the photoelectric conversion device is disposed on an optical path after the light convergence device; a rechargeable battery which is electrically connected with the photoelectric conversion device and used for storing electrical energy and externally providing electricity; a thermal energy storage device including a heat storage medium, where the heat storage medium is thermally connected to the photoelectric conversion device through a first heat exchange channel and thermally connected to the rechargeable battery through a second heat exchange channel; and a heat dissipation-insulation control mechanism used for controllably, at least partially connecting or insulating a heat exchange between the heat storage medium and outside.

In the energy storage type solar device of the present invention, the thermal energy storage device is used to store the thermal energy, such as the thermal energy generated during the operation of the photoelectric conversion device, and then the heat dissipation-insulation control mechanism is used to control the exchange of the stored thermal energy with the external environment. This way, not only the photoelectric conversion device and the battery can be cooled in hot conditions, but also the battery can be kept warm in cold conditions, thereby enabling the device of the present invention to operate normally under various climatic conditions and having wide adaptability.

The specific examples in accordance with the present disclosure will he described in detail below with reference to the drawings.

### BRIEF DESCRIPTION OF THE DRAWINGS

FIG. 1 is a schematic view of a solar device of embodiment 1;

FIG. 2 is a schematic view of a solar device of embodiment 2;

FIG. 3 is a schematic view of a solar device of embodiment 3;

FIG. 4 is a schematic view of a solar device of embodiment 4; and

FIG. 5 is a schematic view of a solar device of embodiment 5;

### DETAILED DESCRIPTION

### Embodiment 1

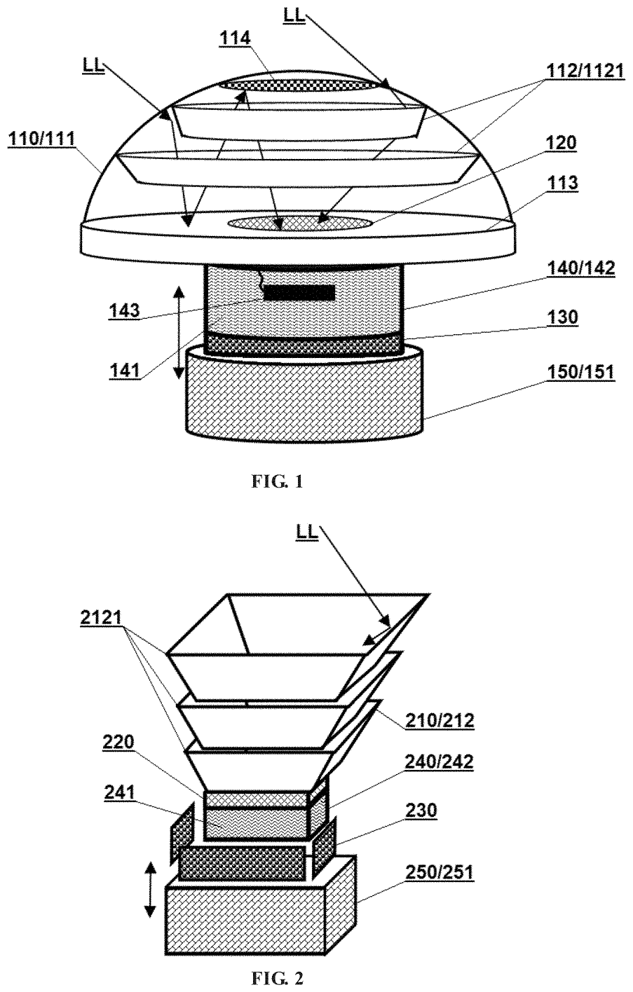

FIG. 1 shows one embodiment of the energy storage type solar device according to the present disclosure, which may include a light convergence device 110, a photoelectric conversion device 120, a rechargeable battery 130, a thermal energy storage device 140, and a heat dissipation-insulation control mechanism 150.

The light convergence device may be used to converge the incident sunlight LL, which makes the utilization to the solar energy more efficient. In a specific implementation, the light convergence device may be implemented in various ways. For example, a single light convergence device or a combination of multiple optical devices can be used. In the present embodiment, the light convergence device 110 may be a combination of various devices, including a transmissive light convergence-type Fresnel lens 111, a blade-type light guide window 112, a reflective light convergence-type Fresnel lens 113, and a reflector 114.

The macroscopic shape of the Fresnel lens 111 may be a hemispherical curved surface, and the macroscopic shape of the Fresnel lens 113 may be planar. A detailed description of the Fresnel lens can be found in the PCT application entitled “Fresnel Lens System” and published on Jun. 2, 2016 with an international publication No. WO/2016/082097, and will not he described again herein. As used herein, a “light convergence-type” “light divergence-type”) Fresnel lens refers to a Fresnel lens having a tooth surface derived from a convex lens surface (or a concave lens surface). The Fresnel lens may be transmissive type or reflective type. A reflective lens may be formed by providing a reflective layer or a reflective coating on one side (or between two sides) of a transmissive lens. Each tooth surface of the Fresnel lens mentioned herein may be either a simple lens surface including only one Fresnel unit or a combined lens surface composed of a plurality of Fresnel units.

The blade-type light guide window 112 is a novel light convergence device, which uses a similar principle as a louver and is capable of guiding lights having incident angles over a relatively large range to a central area of the light guide window. It may include at least two layers of blades 1121. Each layer of blade may be inclined from the top to the center of the bottom in the direction in which the sunlight is incident, and at least one side of the layer of blade facing the top may be a reflective surface capable of reflecting lights (in this embodiment, both sides of the blade are reflective surface). The blades may be used to converge the lights incident from the top toward the center of the bottom. Specifically, the blade may be a closed ring with a symmetrical shape, and the multiple layers of blades may be coaxially arranged and different in size. Alternatively, the blades may be strip-shaped, and multiple layers of blades may be arranged symmetrically with respect to the center of the bottom. An example in which the blades are inclined circular rings is shown in FIG. 1.

In other embodiments, devices 111, 112 and 113 can be used independently for convergence of light. In other embodiments, the transmissive light convergence-type Fresnel lens 111 may also be replaced with a conventional transparent cover having no convergence effect. In other embodiments, other optical devices may alternatively or additionally be used so as to increase the concentration ratio or increase the ability to adapt to changes in the angle of incidence of the light.

The photoelectric conversion device may generally refer to all devices that directly convert light energy into electrical energy, including various photovoltaic panels, photovoltaic films, quantum dot photoelectric conversion devices, and the like. in this embodiment, a photovoltaic panel 120 may be used, and the light receiving surface thereof may be disposed on the optical path after the light convergence device 110. Specifically, the incident sunlight LL may reach the reflective lens 113 after being sequentially concentrated by the lens 111 and the light guide window 112, and then reach the reflector 114 after being concentrated and reflected by the reflective lens 113, and thereafter be reflected to the light receiving surface of the photovoltaic panel 120 (disposed on the central area of the reflective lens 113), thereby allowing both light energy and thermal energy to be more concentrated.

The rechargeable battery 130 may be electrically connected to the photovoltaic panel 120 (not shown) for storing electrical energy and externally providing electricity.

The thermal energy storage device 140 may include a thermal storage medium 141 for absorbing and storing thermal energy. The heat storage medium may be any medium having a large heat capacity. For example, the heat storage medium may be one selected from, or a mixture containing at least one selected from, the group of melted salt, paraffin, water, oil, alcohol, ether, Freon, silica gel, etc. A coolant which is not easily frozen can be preferable, such that the device has a stronger temperature adaptability.

The heat storage medium may be thermally connected to the photoelectric conversion device through a first heat exchange channel, and be thermally connected to the rechargeable battery through a second heat exchange channel. The correspondingly disposed heat dissipation-insulation control mechanism may be used for controllably, at least partially connecting or insulating the heat exchange between the heat storage medium and the outside, thereby achieving cooling or heat preservation of the rechargeable battery.

In accordance with the present disclosure, specifically, the battery, the photovoltaic panel and thermal energy storage device may be arranged in various different relative positional relationships, thereby presenting different specific configurations. However, these specific configurations may have the common features described above, namely, the temperature of the photovoltaic panel and the battery will be adjusted by the heat storage medium and the heat exchange between the heat storage medium and the outside will be controlled by the heat dissipation-insulation control mechanism.

In the present embodiment, the thermal energy storage device 140 may include a container 142 which has a top wall, a bottom wall and a side wall connecting the top wall and the bottom wall (to facilitate the display, the container in the figures is transparent, but actually, it can also be opaque, which will not be described below). The top wall, the bottom wall and the side wall may be at least partially made of a thermally conductive material, for example, made of metal. The top wall may act as the first heat exchange channel, and the photovoltaic panel 120 may be disposed on the outer side of the top wall. The bottom wall may act as the second heat exchange channel, and the battery 130 may be disposed on the outer side of the bottom wall. The sidewall may act as the main channel for heat exchange between the heat storage medium and the outside. In other embodiments, the positional relationship between the battery, the photovoltaic panel and the container may be changed such that at least two of the top wall, the bottom wall and the side wall respectively act as one of the first heat exchange channel and the second heat exchange channel, and the remaining wall, if it is made of a heat-conducting material, acts as the main channel for heat exchange between the heat storage medium and the outside. If all of them are made of heat insulating materials, the heat storage medium may exchange heat with the outside indirectly through the battery.

The heat dissipation-insulation control mechanism 150 may include a movable insulation layer made of a heat insulating material. The rechargeable battery or the other portion of the container other than the wall acting as the first heat exchange channel may be capable of being at least partially removably covered by the movable insulation layer. In the present embodiment, the movable insulation layer may include a sleeve 151 which is axially movable along the sidewall (as indicated by the two-way arrow in FIG. 1) to cover or expose the sidewall. When the sleeve 151 is slid downward so that the side wall of the container 142 is exposed, the heat storage medium 141 may exchange heat with the outside air. At this time, the thermal energy storage device acts as a cooler. When the sleeve 151 is slid upward to close the side wall of the container 142, the thermal energy storage device acts as a thermal insulation device.

In other embodiments, the movable insulation layer may further include a bottom plate which closes one end of the sleeve such that, when the sleeve is in a position where it covers the side wall, the rechargeable battery is located between the bottom wall of the container and the bottom plate. Further, the bottom plate and the sleeve may be connected in a fixed or movable manner, and when connected in a movable manner, the bottom plate can be opened to expose the rechargeable battery.

As a preferred embodiment, an electric heater 143 may further be provided in the embodiment, and may be specifically disposed in the thermal energy storage device 140. The electric heater may be electrically connected to the photoelectric conversion device or the rechargeable battery, and be used to heat the heat storage medium in the thermal energy storage device, such that, in the case where the temperature is too low, the required temperature can be maintained by electric heating.

In other embodiments, preferably, one or more thermoelectric conversion devices may be further disposed. Specifically, the one or more thermoelectric conversion devices may be disposed on at least one heat exchange channel of the thermal energy storage device for generating electricity using the heat flowing through, thereby achieving higher solar energy usage efficiency. The electrical energy generated by the thermoelectric conversion device may also be stored in a rechargeable battery.

In other embodiments, preferably, a control device may be further provided, which may be used to connect at least one detection device disposed in the thermal energy storage device and control the operation of other devices according to the data collected by the detection device. For example, the control device may control the charging and discharging of the rechargeable battery, control the movement of the heat dissipation-insulation control mechanism, control the heating of the electric heater, and the like. The detection device used may be selected from a temperature sensor and a pressure sensor.

In other embodiments, preferably, various devices with different functions may be further integrated to enhance or enrich the functionality of the device, For example, an illumination lamp, a motion detection device, a surveillance camera, a communication device, and the like may be further provided.

### Embodiment 2

FIG. 2 shows another embodiment of the energy storage type solar device according to the present disclosure, which may include a light convergence device 210, a photovoltaic panel 220, a rechargeable battery 230, a thermal energy storage device 240, and a heat dissipation-insulation control mechanism 250.

The light convergence device 210 in this embodiment may be a single light convergence device, that is, a blade-type light guide window 212. The blade-type light guide window 212 may include a three-layer blade 2121. Both sides of the blade may be reflective surfaces, and each layer of blade may have an inclined closed ring shape and a quadrangular cross section. The blades in this embodiment are closed rings, and therefore it is equivalent to being provided with blades in four sides of east, south, west and north. In other embodiments, non-closed blades may also be used, For example, strip-shaped blades may be disposed symmetrically only in east and west sides or south and north side, while simple single mirror is used in the remaining side.

The light receiving surface of the photovoltaic panel 220 may be disposed at the bottom of the light guide window 212, and the incident sunlight LL may be concentrated thereon by the light guide window.

The thermal energy storage device 240 may be similar to that of the embodiment 1, and may include a heat storage medium 241 and a container 242. The photovoltaic panel 220 may be disposed outside of the top wall of the container 242,

Different from the embodiment 1, the rechargeable battery 230 may be disposed at outside of the side wall of the container 242 (to facilitate the display, the battery 230 and the container 242 are separately shown in FIG. 2, but in fact, the battery 230 surrounds and is closely attached to the side wall of the container 242). The bottom wall of the container 242 may be made of a heat insulating material such that heat exchange between the heat storage medium and the outside is mainly performed indirectly through the battery 230.

The heat dissipation-insulation control mechanism 250 may include a movable insulation layer made of a heat insulating material, which may specifically be a sleeve 251 being axially movable along the surface of the rechargeable battery to cover or expose the rechargeable battery. When the sleeve 251 is slid downward, the heat storage medium 241 may exchange heat with the outside air through the side walls of the container and the rechargeable battery. When the sleeve 251 is slid upward to close, the thermal energy storage device may act as a thermal insulation device.

### Embodiment 3

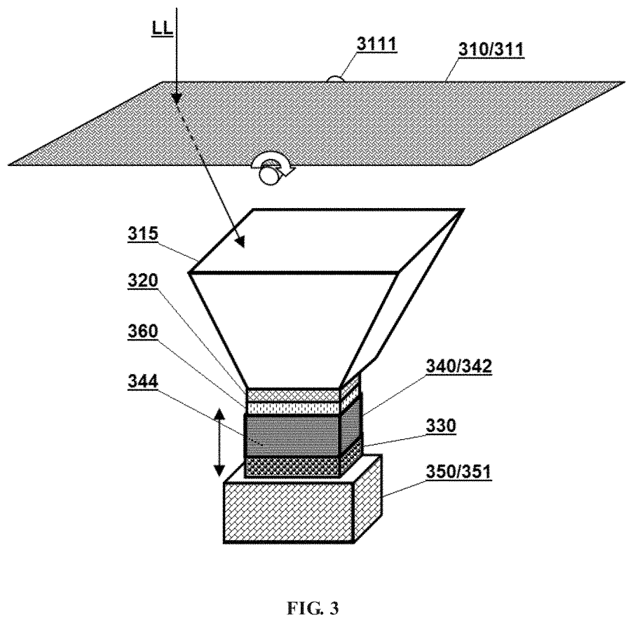

FIG. 3 shows another embodiment of the energy storage type solar device according to the present disclosure, which may include a light convergence device 310, a photovoltaic panel 320, a rechargeable battery 330, a thermal energy storage device 340 and a heat dissipation-insulation control mechanism 350.

The light convergence device 310 in this embodiment may be composed of two optical devices, including a transmissive light convergence-type Fresnel lens 311 and a light convergence funnel 315, thereby having a high concentrating ratio and being able to be used in a very cold region. The macroscopic shape of the Fresnel lens 311 may be planar. As a preferred embodiment, it may be provided on a single-axis sun-tracking device. For the sake of simplicity, only the rotation shaft 3111 of the sun-tracking device is shown in FIG. 3. By rotating the rotation shaft, the tilt angle of the lens 311 can be changed, thereby better adapting to changes in the incident angle of the sunlight.

The light convergence funnel 315 may have a larger opening at one end and a smaller opening at the other end, and the inner wall thereof may be at least partially a reflective surface. The light convergence funnel 315 may be used to concentrate light incident from the end with larger opening toward the end with smaller opening. The light convergence funnel may have an inclined reflective surface similar to the blade-type light guide window. The difference is that the side wall of the light convergence funnel is a complete smooth continuous surface, while the side wall of the light guide window is formed by overlapped multiple layers of blades. In some embodiments, the light guide window can be used in combination with the light convergence funnel. For example, a multi-layer blade structure of the light guide window may be used on the east and west sides, while a smooth mirror of the light convergence funnel may be used on the south and north sides.

The light receiving surface of the photovoltaic panel 320 may be disposed at the bottom of the light convergence funnel 315, and the incident sunlight LL may irradiate thereon after being sequentially concentrated by the lens 311 and the light convergence funnel 315.

The thermal energy storage device 340 may be similar to that of the embodiment 1, and may include a heat storage medium (not shown) and a container 342 made of a heat conductive material. The photovoltaic panel 320 may be disposed at outside of the top wall of the container. The battery 330 may be disposed at outside the bottom wall of the container. As an alternative embodiment, a photothermal conversion device 344 may be further disposed on the sidewall of the container, so as to better utilizing the solar energy to heat the heat storage medium.

The heat dissipation-insulation control mechanism 350 may employ a sleeve 351 made of a heat insulating material which is axially movable along the surface of the photothermal conversion device to close or expose the photothermal conversion device. The sleeve 351 may further have a closed bottom plate (not shown), and the rechargeable battery may be located between the bottom wall of the container and the bottom plate of the sleeve, thereby achieving better thermal insulation to adapt to cold weather.

As a preferred embodiment, the present embodiment may further include a thermoelectric conversion device 360 disposed on the first heat exchange channel, that is, between the photovoltaic panel 320 and the top wall of the container 342, and used for generating electricity using the heat passing through. In other embodiments, the thermoelectric conversion device may also be disposed on other heat exchange channels of the thermal energy storage device. Alternatively, more thermoelectric conversion devices may be provided.

### Embodiment 4

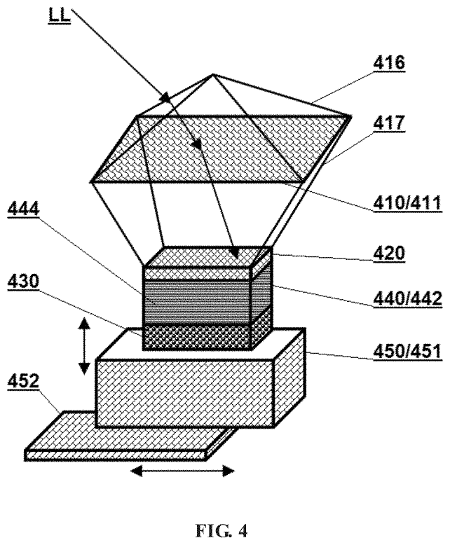

FIG. 4 shows another embodiment of the energy storage type solar device according to the present disclosure, which may include a light convergence device 410, a photovoltaic panel 420, a rechargeable battery 430, a thermal energy storage device 440, and a heat dissipation-insulation control mechanism 450.

The light convergence device 410 in this embodiment may be composed of a plurality of optical devices, including a tapered transparent top cover 416, a transmissive light convergence-type Fresnel lens 411, and a reverse tapered transparent funnel 417. The macroscopic shape of the Fresnel lens 411 may be planar. The Fresnel lens 411 may form a first closed cavity together with the transparent top cover 416, and form a second closed cavity together with the transparent funnel 417. As a preferred embodiment, one or both of the first and second closed cavities may be filled with an optical gas. The optical gas may have a refractive index greater than that of air under the same physical conditions, such that the cavity filled with the optical gas form a gas lens, thereby achieving a better concentrating effect.

The light receiving surface of the photovoltaic panel 420 may be disposed at the bottom of the transparent funnel 417, and the incident sunlight LL may irradiate thereon after being sequentially concentrated by the first closed cavity (gas lens), the lens 411 and the second closed cavity (gas lens).

The thermal energy storage device 440 may be similar to that of the embodiment 3, and may include a heat storage medium (not shown) and a container 442 made of a heat conductive material. The photovoltaic panel 420 may be disposed at outside of the top wall of the container. The battery 430 may be disposed at outside the bottom wall of the container. A photothermal conversion device 444 may also be disposed on the side wall of the container.

The heat dissipation-insulation control mechanism 450 may be similar to that in the embodiment 3, and may include a sleeve 451 made of a heat insulating material. The sleeve 451 may be axially movable along the surface of the photothermal conversion device to close or expose the photothermal conversion device. Different from the embodiment 3, a movable bottom plate 452 may further be provided. The battery 430 may be located between the bottom wall of the container 442 and the bottom plate 452. The bottom plate 452 may be horizontally movable along the end surface of the sleeve 451 so as to close or open the end face of the sleeve 451, thereby facilitating temperature control.

### Embodiment 5

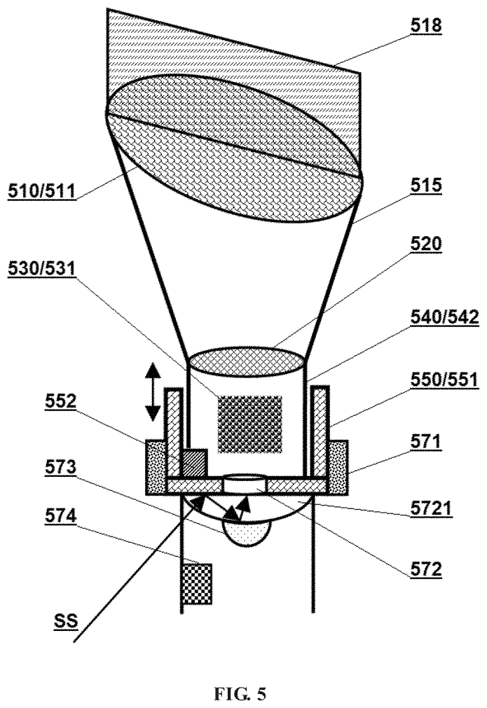

FIG. 5 shows another embodiment of the energy storage type solar device according to the present disclosure, which may include a light convergence device 510, a photovoltaic panel 520, a rechargeable battery 530, a thermal energy storage device 540, and a heat dissipation-insulation control mechanism 550.

The light convergence device 510 in this embodiment may be composed of a plurality of optical devices, including a light convergence funnel 515, a transmissive light convergence-type Fresnel lens 511, and a linear light divergence-type Fresnel lens 518.

The light convergence funnel 515 may be a funnel having an irregular length. The inner wall of the light convergence funnel 515 may be a reflective surface, and the end surface of the end with larger opening may be inclined. The inclined end surface may be symmetrical in east-west direction while asymmetrical in north-south direction.

The macroscopic shapes of the Fresnel lenses 511 and 518 may be both planar. The lens 511 may he covered on the inclined end surface of the light convergence funnel so as to enhance the convergence effect while prevent foreign matter from falling into the light convergence funnel. The lens 518 may be disposed substantially vertically on the inclined end surface of the light convergence funnel with respect to the horizontal plane, and specifically, may be disposed in the north-south direction (i.e., disposed along the axis of symmetry of the inclined end faces) for improving the concentrating ability in the east-west direction. The lens 518 may be a linear light divergence-type Fresnel lens. The so-called “linear” lens may generally mean that the focus center of the lens is a line. An advantage of applying “linear” light divergence in the present disclosure is that the light is diverged only in one direction. For example, a linear light divergence-type lens can be a Fresnel lens whose tooth surface is derived from a concave cylindrical surface, a concave elliptical cylinder surface or a concave polynomial cylinder. The “substantially vertically” mentioned herein may mean that the angle between the lens 518 and the horizontal plane is between 60 and 120 degrees.

The light receiving surface of the photovoltaic panel 520 may be disposed at one end of the light convergence funnel 515 with smaller opening. By combining the Fresnel lens with the light convergence funnel in this embodiment, it is possible to obtain a concentrating ratio of 3 to 10 on the photovoltaic panel without using the sun-tracking device.

The thermal energy storage device 540 may include a heat storage medium (not shown) and a container 542 made of metal. The photovoltaic panel 520 may be disposed at outside of the top wall of the container, In other embodiments, at least two of the top wall, the bottom wall and the side wall of the container may be at least partially made of a thermally conductive material, one of which acts as the first heat exchange channel with the photovoltaic panel and the other acts as the heat exchange with the outside.

The rechargeable battery 530 may be disposed inside the container 542 through a sealed battery compartment 531. The sealed battery compartment 531 may be at least partially made of a thermally conductive material, and act as the second heat exchange channel.

The heat dissipation-insulation control mechanism 550 may include a movable insulation layer made of a heat insulating material which removably covers the outside of the wall of the container used for heat exchange with the outside. In this embodiment, the movable insulation layer may be specifically a sleeve 551 which may be moved axially along the side wall of the container 542 under the control of a drive mechanism 552 so as to cover or expose the side wall.

Preferably, the solar device of the present embodiment may further integrate various devices with different functions, and may be powered by a rechargeable battery, so as to adapt to various application requirements. The integrated devices may specifically include:

An illumination lamp 571 for providing illumination, The illumination lamp may be specifically an LED lamp or a laser lamp. Providing the illumination lamp may allow the solar device of the present embodiment to act as a solar street light, in which the need for wiring can be omitted since the power is provided by the energy storage type solar device.

A surveillance camera 572 used for collecting image data. The surveillance camera may use a single-reflection or dual-reflection 360-degree panoramic lens. The term “single-reflection” or “dual-reflection” means that the incident light SS reach the photosensitive chip by one or two times of reflection. What is shown in FIG. 5 is a dual-reflection panoramic lens 5721.

A motion detection device 573 used for generating a detection signal when a moving object is detected. The motion detection device may preferably he a panoramic motion detection device. The generated detection signal may be used to control the operation of other devices. For example, it may be used to activate the surveillance camera 572 to take a picture or video, or may be used to activate the switch of the light 571, thereby saving battery consumption.

A communication device 574 used for wireless communication with the outside. For example, it may be used to transmit image data generated by surveillance camera 572, or may be used to communicate with other solar devices in the vicinity, or may be used to act as a base station or hotspot for wireless communication.

The principles and embodiments of the present disclosure have been described with reference to specific examples. It shall be understood that the embodiments above are only intended to facilitate the understanding to the present disclosure, but shall not be construed as limitations thereto. Variations to the above-described embodiments may be made by those skilled in the art in light of the teachings of the present disclosure, such as simple exchanges between and utility improvement to the various modules in the above-described embodiments.

1. An energy storage type solar device, comprising:
a light convergence device used for converging incident sun lights;
a photoelectric conversion device used for converting received light energy into electrical energy, wherein a light receiving surface of the photoelectric conversion device is disposed on an optical path after the light convergence device;
a rechargeable battery which is electrically connected with the photoelectric conversion device and used for storing electrical energy and externally providing electricity;
a thermal energy storage device comprising a heat storage medium, wherein the heat storage medium is thermally connected to the photoelectric conversion device through a first heat exchange channel and thermally connected to the rechargeable battery through a second heat exchange channel; and
a heat dissipation-insulation control mechanism used for controllably, at least partially connecting or insulating a heat exchange between the heat storage medium and outside.

2. The device of claim 1, wherein the light convergence device comprises at least one of:
a light convergence-type Fresnel lens which is transmissive type or reflective type;
a blade-type light guide window, wherein, the blade-type light guide window comprises at least two layers of blade, each layer of blade is inclined from a top to a center of a bottom in a direction in which a sunlight is incident, at least one side of the layer of blade facing the top is a reflective surface capable of reflecting lights, and the blades are used to converge lights incident from the top toward the center of the bottom;
a light convergence funnel, wherein, the light convergence funnel has a larger opening at one end and a smaller opening at the other end, an inner wall of the light convergence funnel is at least partially a reflective surface, and the light convergence funnel is used to concentrate lights incident from the end with larger opening toward the end with smaller opening;
a linear light divergence-type Fresnel lens which is disposed substantially vertically with respect to a horizontal plane; and
a gas lens which comprises an optical gas filled in a closed cavity, wherein the optical gas has a refractive index greater than that of air under the same physical conditions.

3. The device of claim 1, further comprising:
an electric heater which is electrically connected with the photoelectric conversion device or the rechargeable battery and used to heat the heat storage medium in the thermal energy storage device.

4. The device of any one of claim 1, wherein:
the heat storage medium is one selected from, or a mixture containing at least one selected from, a group of melted salt, paraffin, water, oil, alcohol, ether, Freon and silica gel.

5. The device of any one of claim 1, further comprising:
a thermoelectric conversion device which is disposed on at least one heat exchange channel of the thermal energy storage device and used to generate electricity using a heat flowing through.

6. The device of any one of claim 1, wherein:
the thermal energy storage device comprises a container which has a top wall, a bottom wall and a side wall connecting the top wall and the bottom wall, and at least two of the top wall, the bottom wall and the side wall are at least partially made of a thermally conductive material and respectively act as one of the first heat exchange channel and the second heat exchange channel; and
the heat dissipation-insulation control mechanism comprises a movable insulation layer made of a heat insulating material, and the rechargeable battery or an other portion of the container other than a wall acting as the first heat exchange channel is at least partially removably covered by the movable insulation layer.

7. The device of claim 6, wherein:
the photoelectric conversion device is disposed at outside of the top wall of the container, the rechargeable battery is disposed at outside of the bottom wall of the container, and the side wall of the container is at least partially made of a heat conductive material; and
the movable insulation layer comprises a sleeve which is axially movable along the side wall to cover or expose the side wall.

8. The device of claim 7, wherein:
the movable insulation layer further comprises a bottom plate which is used to close one end of the sleeve, and when the sleeve is in a position covering the side wall, the rechargeable battery is located between the bottom wall of the container and the bottom plate; and
the bottom plate and the sleeve are connected in a fixed or movable manner, and when connected in a movable manner, the bottom plate is able to be opened to expose the rechargeable battery.

9. The device of claim 6, wherein:
the photoelectric conversion device is disposed at outside of the top wall of the container, the rechargeable battery is disposed at outside of the side wall of the container, and the bottom wall of the container is made of a heat insulating material; and
the movable insulation layer comprises a sleeve which is axially movable along a surface of the rechargeable battery to cover or expose the rechargeable battery.

10. The device of any one of claim 1, wherein:
the thermal energy storage device comprises a container which has a top wall, a bottom wall and a side wall connecting the top wall and the bottom wall, and at least two of the top wall, the bottom wall and the side wall are at least partially made of a thermally conductive material, one of which acts as the first heat exchange channel and the other is used for a heat exchange with outside;
the rechargeable battery is disposed inside the container through a sealed battery compartment, and the battery compartment is at least partially made of a thermally conductive material and acts as the second heat exchange channel; and
the heat dissipation-insulation control mechanism comprises a movable insulation layer made of a heat insulating material, and the movable insulation layer removably covers an outside of a wall for heat exchange with outside of the container.

11. The device of claim 10, wherein:
the photoelectric conversion device is disposed at outside of the top wall of the container, and the side wall of the container is used for exchanging heat with outside; and
the movable insulation layer comprises a sleeve which is axially movable along the side wall to cover or expose the side wall.

12. The device of claim 6, wherein:
the light convergence device comprises:
a light convergence funnel, wherein, the light convergence funnel has a larger opening at one end and a smaller opening at the other end, an inner wall of the light convergence funnel is a reflective surface, an end surface of the end with larger opening is inclined, the inclined end surface is symmetrical in an east-west direction while asymmetrical in a north-south direction, and a light receiving surface of the photoelectric conversion device is arranged at the end with smaller opening of the light convergence funnel; and
a transmissive light convergence-type Fresnel lens which covers the inclined end surface of the light convergence funnel.

13. The device of claim 12, wherein:
the light convergence device further comprises:
a linear light divergence-type Fresnel lens which is disposed substantially vertically on the inclined end surface of the light convergence funnel with respect to a horizontal plane.

14. The device of any one of claim 1, further comprising at least one of:
a control device which is used to connect at least one detection device disposed in the thermal energy storage device and control a charging and a discharging of the rechargeable battery and control a movement of the heat dissipation-insulation control mechanism according to a data collected by the detection device, wherein the detection device is selected from a temperature sensor and a pressure sensor;
an illumination lamp used for providing illumination;
a surveillance camera used for collecting an image data;
a motion detection device used for generating a detection signal when a moving object is detected, wherein the detection signal is used to control an operation of other device; and
a communication device used for wireless communication with outside.

15. The device of claims 10, wherein:
the light convergence device comprises:
a light convergence funnel, wherein, the light convergence funnel has a larger opening at one end and a smaller opening at the other end, an inner wall of the light convergence funnel is a reflective surface, an end surface of the end with larger opening is inclined, the inclined end surface is symmetrical in an east-west direction while asymmetrical in a north-south direction, and a light receiving surface of the photoelectric conversion device is arranged at the end with smaller opening of the light convergence funnel; and
a transmissive light convergence-type Fresnel lens which covers the inclined end surface of the light convergence funnel.

16. The device of claim 15, wherein:
the light convergence device further comprises:
a linear light divergence-type Fresnel lens which is disposed substantially vertically on the inclined end surface of the light convergence funnel with respect to a horizontal plane.
